(19) United States
(12) Patent Application Publication
(10) Pub. No.: US 2023/0090846 A1
(43) Pub. Date: Mar. 23, 2023

(54) METHOD AND DEVICE FOR DETECTING DEFECTS IN AIRCRAFT TEMPLATE

(71) Applicant: Nanjing University of Aeronautics and Astronautics, Nanjing (CN)

(72) Inventors: Jun WANG, Nanjing (CN); Chunliang HUANG, Nanjing (CN); Hongwei LI, Nanjing (CN); Jianping YANG, Nanjing (CN)

(21) Appl. No.: 17/981,594

(22) Filed: Nov. 7, 2022

(30) Foreign Application Priority Data
Nov. 5, 2021 (CN) 202111303325.3

(51) Int. Cl. G06F 30/15; G06F 30/20

(52) U.S. Cl. CPC G06F 30/15; G06F 30/20

(57) ABSTRACT

A method for detecting defects of an aircraft template, including: scanning the template; establishing a local coordinate system of a template point cloud; fitting plane parameters of a target local point cloud; acquiring an average of normal vectors of all points; calculating heights of all points; calculating an angle between a normal vector of the sinking point and a normal vector of the template point cloud plane; binarizing a point cloud image of the template; obtaining a 3D digital model of the template; aligning the 3D digital model with a resulting point cloud; and determining whether an actual distance exceeds a preset distance threshold, if not, the template is qualified, otherwise, determining whether the number of points whose actual distance exceeds the preset distance threshold exceeds a preset number threshold; if not, the template is qualified; otherwise, the template is not qualified. A detection device is also provided.

### CROSS-REFERENCE TO RELATED APPLICATIONS

This application claims the benefit of priority from Chinese Patent Application No. 202111303325.3, filed on Nov. 5, 2021. The content of the aforementioned application, including any intervening amendments thereto, is incorporated herein by reference in its entirety.

### TECHNICAL FIELD

This application relates to template inspection, in particular to a method and device for detecting defects in an aircraft template.

### BACKGROUND

Lofting-template technology is the bridge between aircraft design and manufacturing. Specifically, a real profile is drawn according to an aircraft pattern; various machining members are manufactured according to related standard; and parts for individual machining members are manufactured. The lofting is performed by drawing the parts and structures of the aircraft on a drawing board according to an actual size (1:1), and the real pattern is called the lofting. The template is a plane measuring tool, which is the reference for processing and inspecting curved parts, assemblies and process equipment. The lofting-template design is to accurately make a shape of a part or assembly based on the actual size according to the aircraft structural pattern and manufacturing requirements.

The lofting performed on a steel plate can ensure the accuracy and uniqueness. However, it is not possible to directly process and inspect an internal lofting in the process of template manufacturing since the steel plate is bulky and opaque, and an auxiliary tool or mold is required for positioning inspection. In contrast, the polyester film has a certain hardness and good transparency and flexibility, and is not easy to age. Moreover, the polyester film can be used in conjunction with the three-dimensional template. Therefore, the polyester film has become a basic medium for drawing lofting data. The lofting originally drawn on the polyester film is used for the processing and inspection of the template. The template is directly subjected to inspection after manufactured, and if the template does not match the lofting, the template will be calibrated according to the lofting.

However, the template inspection relies on manual observation, which struggles with poor accuracy, high labor intensity and material cost and low inspection efficiency.

### SUMMARY

In order to solve the problems in the prior art that the manual visual inspection has poor accuracy, high labor intensity and material cost, and low inspection efficiency, the present disclosure provides a method and device for detecting defects of an aircraft template.

The technical solutions of the present disclosure are described as follows.

In a first aspect, this application provides a method for detecting defects of an aircraft template, comprising:

(S1) scanning the aircraft template to obtain a zero-mean template point cloud;

(S2) establishing a local coordinate system of a template point cloud based on the zero-mean template point cloud;

(S3) rasterizing the template point cloud to obtain a plurality of local point clouds;

(S4) fitting a plane parameter of a target local point cloud to obtain a normal vector of the target local point cloud on a template point cloud plane and any point on the template point cloud plane;

(S5) acquiring an average of normal vectors of all points in the target local point cloud;

(S6) calculating a height of all points in the target local point cloud based on the average of the normal vectors of all points in the target local point cloud to obtain a sinking point in the target local point cloud;

(S7) calculating an angle between a normal vector of the sinking point in the target local point cloud and a normal vector of the template point cloud plane where the sinking point is located to obtain a cutting point of the aircraft template; wherein all cutting points of the aircraft template constitute a cutting line;

(S8) binarizing a point cloud image of the aircraft template to obtain outer contour points of the aircraft template; wherein the outer contour points constitute an outer contour of the aircraft template;

(S9) merging all cutting points and outer contour points of the aircraft template to obtain a resulting point cloud;

(S10) obtaining a three-dimensional (3D) digital model of the aircraft template;

(S11) aligning the 3D digital model with the resulting point cloud;

(S12) calculating a distance between a target point in the 3D digital model and a corresponding point in the resulting point cloud to obtain an actual distance; and

(S13) determining whether the actual distance exceeds a preset distance threshold;

if not, confirming that the aircraft template is qualified;

otherwise, determining whether the number of points in the resulting point cloud of which the actual distance exceeds the preset distance threshold exceeds a preset number threshold;

if not, confirming that the aircraft template is qualified;

otherwise, determining that the aircraft template is not qualified.

In an embodiment, the step (S2) is performed through steps of: (S201) calculating a product of a 3×n matrix formed from the zero-mean template point cloud and a transpose matrix of the 3×n matrix to obtain a covariance matrix; wherein n represents the number of points in the zero-mean template point cloud;

(S202) calculating three eigenvectors a₁, a₂ and a₃ of the covariance matrix which are mutually orthogonal; wherein λ₁ is an eigenvalue of a₁, λ₂ is an eigenvalue of a₂, λ₃ is an eigenvalue of a₃, and λ₁>λ₂>λ₃; and

(S203) establishing the local coordinate system of the template point cloud by taking the three eigenvectors a₁, a₂ and a₃ respectively as X₁-axis direction, Y₁-axis direction and Z₁-axis direction of the local coordinate system, and taking a zero point O₁ as an origin of the local coordinate system.

In an embodiment, the step (S6) is performed through steps of:

(S601) calculating the height of all points in the target local point cloud according to the following formula:

$${h}_{ji} = \{ \begin{matrix}\frac{( {p}_{ji} - {p}_{j 0} ) \cdot {v}_{j}}{\vert {v}_{j} \vert} & {v}_{j} \cdot \overline{{v}_{j}} < 0 \\ \frac{( {p}_{j 0} - {p}_{j i} ) \cdot {v}_{j}}{\vert {v}_{j} \vert} , & {v}_{j} \cdot \overline{{v}_{j}} \geq 0\end{matrix} ;$$

wherein v̅ⱼ̅ represents an average of normal vectors of all points in a target local point cloud j; vⱼ represents a normal vector of the target local point cloud j on the template point cloud plane; pⱼᵢ represents an i^{th} point in the target local point cloud j; pⱼ₀ represents any point in the target local point cloud j; and hⱼᵢ represents a height of the i^{th} point in the target local point cloud j; and

(S602) setting a target height threshold; wherein a point in the target local point cloud whose height is less than the target height threshold is the sinking point.

In an embodiment, the step (S7) is performed through steps of:

(S701) calculating the angle between the normal vector of the sinking point in the target local point cloud and the normal vector of the template point cloud plane where the sinking point is located according to the following formula:

$${r}_{ji} = arccos \frac{{v}_{j i} \cdot {v}_{j}}{\vert {v}_{j} \vert} ;$$

wherein rⱼᵢ represents an angle between a normal vector of an i^{th} sinking point in a target local point cloud j and a normal vector of a template point cloud plane where the i^{th} sinking point is located; vⱼ represents a normal vector of the target local point cloud j on the template point cloud plane; and vⱼᵢ represents the normal vector of the i^{th} sinking point in the target local point cloud j; and

(S702) setting a target angle threshold; wherein a sinking point in the target local point cloud corresponding to an angle less than the target angle threshold is the cutting point.

In an embodiment, the step (S8) is performed through steps of:

(S801) calculating a distance between a target point in the template point cloud and a point closest to the target point;

(S802) calculating a spatial resolution of the template point cloud according to the following formula:

$$l = \frac{1}{n} {\sum }_{i = 1}^{n} {d}_{i} ;$$

wherein l represents the spatial resolution of the template point cloud; n represents the total number of points in the template point cloud; and dᵢ represents a distance between an i^{th} point in the template point cloud and a point closest to the i^{th} point;

(S803) dividing an X₁O₁Y₁ plane into a plurality of grids with the spatial resolution as an interval to obtain a binary image; wherein each of the plurality of grids is a pixel of the binary image; and an initial value of each pixel in the binary image is set to 0;

(S804) traversing all points in the template point cloud, and setting pixels corresponding to grids where the points in the template point cloud are respectively located as 1-value pixels;

(S805) traversing all 0-value pixels in the binary image, and setting a target 0-value pixel as a 1-value pixel, wherein in surrounding 8 pixels of the target 0-value pixel, the number of 1-value pixels exceeds a target number;

(S806) traversing all 1-value pixels in the binary image, and taking a 1-value pixel adjacent to a 0-value pixel as a contour pixel; and

(S807) taking a point in a grid corresponding to the contour pixel as the outer contour point of the aircraft template.

In a second aspect, this application also provides a device for detecting defects in an aircraft template, comprising:

a template scanning module;

a coordinate system building module;

a rasterization module;

a plane fitting module;

a first acquisition module;

a first calculation module;

a second calculation module;

an image binarization module;

a merging module;

a second acquisition module;

an alignment module;

a third calculation module;

a first judgment module;

a first confirmation module;

a second judgment module;

a second confirmation module; and

a third confirmation module;

wherein the template scanning module is configured to scan the aircraft template to obtain a zero-mean template point cloud;

the coordinate system building module is configured to establish a local coordinate system of a template point cloud based on the zero-mean template point cloud;

the rasterization module is configured to rasterize the template point cloud to obtain a plurality of local point clouds;

the plane fitting module is configured to fit a plane parameter of a target local point cloud to obtain a normal vector of the target local point cloud on a template point cloud plane and any point on the template point cloud plane;

the first acquisition module is configured to acquire an average of normal vectors of all points in the target local point cloud;

the first calculation module is configured to calculate a height of all points in the target local point cloud based on the average of the normal vectors of all points in the target local point cloud to obtain a sinking point in the target local point cloud;

the second calculation module is configured to calculate an angle between a normal vector of the sinking point in the target local point cloud and a normal vector of the template point cloud plane where the sinking point is located to obtain a cutting point of the aircraft template; wherein all cutting points of the aircraft template constitute a cutting line;

the image binarization module is configured to binarize a point cloud image of the aircraft template to obtain outer contour points of the aircraft template; wherein the outer contour points constitute an outer contour of the aircraft template;

the merging module is configured to merge all cutting points and outer contour points of the aircraft template to obtain a resulting point cloud;

the second acquisition module is configured to acquire a three-dimensional (3D) digital model of the aircraft template;

the alignment module is configured for aligning the 3D digital model with the resulting point cloud;

the third calculation module is configured to calculate a distance between a target point in the 3D digital model and a corresponding point in the resulting point cloud to obtain an actual distance;

the first judgment module is configured for judging whether the actual distance exceeds a preset distance threshold;

the first confirmation module is configured to confirm that the aircraft template is qualified when the actual distance does not exceed the preset distance threshold;

the second judgment module is configured for judging whether the number of points in the resulting point cloud of which the actual distance exceeds the preset distance threshold exceeds a preset number threshold when the first judgment module determines that the actual distance exceeds the preset distance threshold;

the second confirmation module is configured to confirm that the aircraft template is qualified when the number of points in the resulting point cloud of which the actual distance exceeds the preset distance threshold does not exceed the preset number threshold; and

the third confirmation module is configured to confirm that the aircraft template is unqualified when the number of points in the resulting point cloud of which the actual distance exceeds the preset distance threshold exceeds the preset number threshold.

In an embodiment, the coordinate system building module comprises:

a first calculating unit;

a second calculating unit; and a building unit;

wherein the first calculating unit is configured to calculate a product of a 3×n matrix formed from the zero-mean template point cloud and a transpose matrix of the 3×n matrix to obtain a covariance matrix; wherein n represents the number of points in the zero-mean template point cloud;

the second calculating unit is configured to calculate three eigenvectors a₁, a₂ and a₃ of the covariance matrix which are mutually orthogonal; wherein λ₁ is an eigenvalue of a₁, λ₂ is an eigenvalue of a₂, λ₃ is an eigenvalue of a₃, and λ₁>λ₂>λ₃; and

the building unit is configured to establish the local coordinate system of the template point cloud by taking the three eigenvectors a₁, a₂ and a₃ respectively as X₁-axis direction, Y₁-axis direction and Z₁-axis direction of the local coordinate system, and taking a zero point O₁ as an origin of the local coordinate system.

In an embodiment, the first calculation module comprises:

a third calculating unit; and

a height threshold setting unit;

wherein the third calculating unit is configured to calculate the height of all the points in the target local point cloud according to the following formula:

$${h}_{ji} = \{ \begin{matrix}\frac{( {p}_{ji} - {p}_{j 0} ) \cdot {v}_{j}}{\vert {v}_{j} \vert} & , {v}_{j} \cdot {\overline{v}}_{j} < 0 \\ \frac{( {p}_{j 0} - {p}_{ji} ) \cdot {v}_{j}}{\vert {v}_{j} \vert} & , {v}_{j} \cdot {\overline{v}}_{j} \geq 0\end{matrix} ;$$

wherein v̅ⱼ̅represents an average of normal vectors of all points in a target local point cloud j; vⱼ represents a normal vector of the target local point cloud j on the template point cloud plane; pⱼᵢ represents an i^{th} point in the target local point cloud j; pⱼ₀ represents any point in the target local point cloud j; and hⱼᵢ represents a height of the i^{th} point in the target local point cloud j; and

the height threshold setting unit is configured to set a target height threshold; wherein a point in the target local point cloud whose height is less than the target height threshold is the sinking point.

In an embodiment, the second calculation module comprises:

a fourth calculating unit; and

an angle threshold setting unit;

wherein the fourth calculating unit is configured to calculate the angle between the normal vector of the sinking point in the target local point cloud and the normal vector of the template point cloud plane where the sinking point is located according to the following formula:

$${r}_{ji} = arccos \frac{{v}_{ji} \cdot {v}_{j}}{\vert {v}_{j} \vert} ;$$

wherein rⱼᵢ represents an angle between a normal vector of an i^{th} sinking point in a target local point cloud j and a normal vector of a template point cloud plane where the i^{th} sinking point is located; vⱼ represents a normal vector of the target local point cloud j on the template point cloud plane; and vⱼᵢ represents the normal vector of the i^{th} sinking point in the target local point cloud j; and

the angle threshold setting unit is configured to set a target angle threshold; wherein a sinking point in the target local point cloud corresponding to an angle less than the target angle threshold is the cutting point.

In an embodiment, the image binarization module comprises:

a fifth calculating unit;

a sixth calculating unit;

a rasterizing unit;

a first pixel setting unit;

a second pixel setting unit;

a contour pixel extraction unit; and

an outer contour point extraction point;

wherein the fifth calculating unit is configured to calculate a distance between a target point in the template point cloud and a point closest to the target point;

the sixth calculating unit is configured to calculate a spatial resolution of the template point cloud according to the following formula:

$$l = \frac{1}{n} {\sum }_{i = 1}^{n} {d}_{i} ;$$

wherein l represents the spatial resolution of the template point cloud; n represents the total number of points in the template point cloud; and dᵢ represents a distance between an i^{th} point in the template point cloud and a point closest to the i^{th} point;

the rasterizing unit is configured to divide an X₁O₁Y₁ plane into a plurality of grids with the spatial resolution as an interval to obtain a binary image; wherein each of the plurality of grids is a pixel of the binary image; and an initial value of each pixel in the binary image is set to 0;

the first pixel setting unit is configured to traverse all points in the template point cloud and set pixels corresponding to grids where the points in the template point cloud are respectively located as 1-value pixels;

the second pixel setting unit is configured to traverse all 0-value pixels in the binary image and set a target 0-value pixel as a 1-value pixels that, wherein in surrounding 8 pixels of the target 0-value pixel, the number of 1-value pixels exceeds a target number;

the contour pixel extraction unit is configured to traverse all 1-value pixels in the binary image and taking a 1-value pixel adjacent to a 0-value pixel as a contour pixel; and

the outer contour point extraction point is configured to take a point in a grid corresponding to the contour pixel as the outer contour point of the aircraft template.

Compared to the prior art, the present disclosure has the following beneficial effects.

This application provides a method and device for detecting defects of an aircraft template. The method comprises: scanning the aircraft template to obtain a zero-mean template point cloud; establishing a local coordinate system of a template point cloud based on the zero-mean template point cloud; rasterizing the template point cloud to obtain a plurality of local point clouds; fitting a plane parameter of a target local point cloud to obtain a normal vector of the target local point cloud on a template point cloud plane and any point on the template point cloud plane; acquiring an average of normal vectors of all points in the target local point cloud; calculating a height of all points in the target local point cloud based on the average of the normal vectors of all points in the target local point cloud to obtain a sinking point in the target local point cloud; calculating an angle between a normal vector of the sinking point in the target local point cloud and a normal vector of the template point cloud plane where the sinking point is located to obtain a cutting point of the aircraft template; wherein all cutting points of the aircraft template constitute a cutting line; binarizing a point cloud image of the aircraft template to obtain outer contour points of the aircraft template; wherein the outer contour points constitute an outer contour of the aircraft template; merging all cutting points and outer contour points of the aircraft template to obtain a resulting point cloud; obtaining a three-dimensional (3D) digital model of the aircraft template; aligning the 3D digital model with the resulting point cloud; calculating a distance between a target point in the 3D digital model and a corresponding point in the resulting point cloud to obtain an actual distance; and determining whether the actual distance exceeds a preset distance threshold; if not, confirming that the aircraft template is qualified; otherwise, determining whether the number of points in the resulting point cloud of which the actual distance exceeds the preset distance threshold exceeds a preset number threshold; if not, confirming that the aircraft template is qualified; otherwise, determining that the aircraft template is not qualified. The method effectively avoids a manual visual inspection, reduces the inspection cost, and improves an inspection efficiency and inspection accuracy.

### BRIEF DESCRIPTION OF THE DRAWINGS

In order to explain the technical solutions of the present disclosure more clearly, the drawings that need to be used in the embodiments will be briefly described below. It should be understood that presented in the drawings are only some embodiments of the present disclosure, which are not intend to limit the scope of the disclosure. It should be noted that other drawings obtained by those of ordinary skill in the art based on these drawings without paying creative effort should still fall within the scope of the disclosure.

FIG. 1 is a flowchart of a method for detecting defects in an aircraft template according to an embodiment of the present disclosure;

FIG. 2 schematically shows rasterization of a template point cloud according to an embodiment of the present disclosure;

FIG. 3 schematically shows an angle between a normal vector of a sinking point in a target local point cloud and a normal vector of a template point cloud plane where the sinking point is located according to an embodiment of the present disclosure;

FIG. 4 schematically shows distribution of 8 pixels around a 0-value pixel according to an embodiment of the present disclosure; and

FIG. 5 schematically shows a structure of a device for detecting defects in the aircraft template according to an embodiment of the present disclosure.

### DETAILED DESCRIPTION OF EMBODIMENTS

The technical solutions of the present disclosure will be described completely and clearly below with reference to the accompanying drawings and embodiments. Obviously, provided below are merely some embodiments of the disclosure, which are not intended to limit the disclosure. It should be understood that all other embodiments obtained by those skilled in the art based on the content disclosed herein without paying any creative effort shall fall within the scope of the present disclosure.

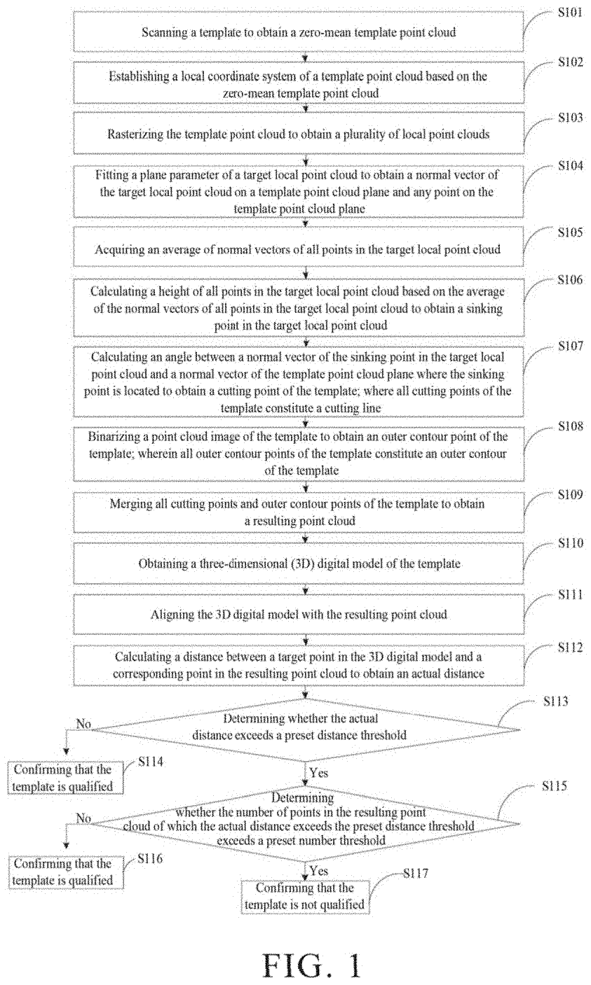

Illustrated in FIG. 1 is a method for detecting defects in an aircraft template, which includes the following steps.

(S1) The aircraft template is scanned to obtain a zero-mean template point cloud.

In step (S1), a three-dimensional measuring instrument is employed to scan the aircraft template to output an original template point cloud, and then coordinate average of the original template point cloud is calculated. All points in the original template point cloud are subjected to subtract the coordinate average to obtain the zero-mean template point cloud P={p₁, p₂, p₃, . . . , pₙ}.

(S2) A local coordinate system of a template point cloud is established based on the zero-mean template point cloud.

(S201) A product of a 3×n matrix formed from the zero-mean template point cloud and a transpose matrix of the 3×n matrix is calculated to obtain a covariance matrix; where n represents the number of points in the zero-mean template point cloud.

(S202) Three eigenvectors a₁, a₂ and a₃ of the covariance matrix which are mutually orthogonal are calculated; where λ₁ is an eigenvalue of a₁, λ₂ is an eigenvalue of a₂, λ₃ is an eigenvalue of a₃, and λ₁>λ₂λ₃.

(S203) The local coordinate system of the template point cloud is established by taking the three eigenvectors a₁, a₂ and a₃ respectively as X₁-axis direction, Y₁-axis direction and Z₁-axis direction of the local coordinate system, and taking a zero point O₁ as an origin of the local coordinate system.

(S3) The template point cloud is rasterized to obtain a plurality of local point clouds.

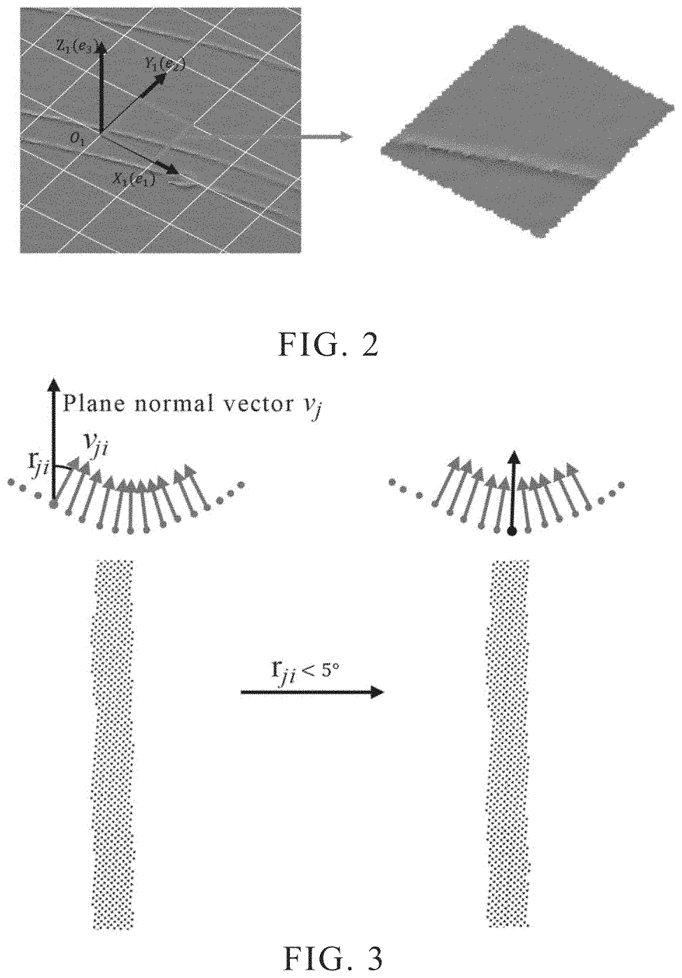

In this step, as shown in FIG. 2, since an entire template is not absolutely flat, there may be slight radians, and a square grid with an interval of 5 mm can be made on an X₁O₁Y₁ plane to divide the template point cloud P={p₁, p₂, p₃, . . . , pₙ} into a plurality of local point clouds to reduce a calculation error in subsequent steps.

(S4) A plane parameter of a target local point cloud is fitted by a random sample consensus (RANSAC) algorithm to obtain a normal vector vⱼ of the target local point cloud on a template point cloud plane and any point p₀ on the template point cloud plane.

(S5) An average of normal vectors of all points in the target local point cloud is obtained by the RANSAC algorithm.

(S6) A height of all points in the target local point cloud are calculated based on the average of the normal vectors of all points in the target local point cloud to obtain a sinking point in the target local point cloud.

(S601) The height of all points in the target local point cloud are calculated according to the following formula:

$${h}_{ji} = \{ \begin{matrix}\frac{( {p}_{ji} - {p}_{j 0} ) \cdot {v}_{j}}{\vert {v}_{j} \vert} & , {v}_{j} \cdot {\overline{v}}_{j} < 0 \\ \frac{( {p}_{j 0} - {p}_{ji} ) \cdot {v}_{j}}{\vert {v}_{j} \vert} & , {v}_{j} \cdot {\overline{v}}_{j} \geq 0\end{matrix} ;$$

where v̅ⱼ̅ represents an average of normal vectors of all points in a target local point cloud j; vⱼ represents a normal vector of the target local point cloud j on the template point cloud plane; pⱼᵢ represents an i^{th} point in the target local point cloud j; pⱼ₀ represents any point in the target local point cloud j; and hⱼᵢ represents a height of the i^{th} point in the target local point cloud j.

(S602) A target height threshold to is usually set as −0.03 mm. A point in the target local point cloud whose height hⱼᵢ is less than the target height threshold to is determined as the sinking point.

(S7) An angle between a normal vector of the sinking point in the target local point cloud and a normal vector of the template point cloud plane where the sinking point is located is calculated to obtain a cutting point of the aircraft template; where all cutting points of the aircraft template constitute a cutting line.

(S701) The angle is calculated according to the following formula:

$${r}_{ji} = arccos \frac{{v}_{ji} \cdot {v}_{j}}{\vert {v}_{j} \vert} .$$

As shown in FIG. 3, rⱼᵢ represents an angle between a normal vector of an i^{th} sinking point in a target local point cloud j and a normal vector of a template point cloud plane where the i^{th} sinking point is located; vⱼ represents a normal vector of the target local point cloud j on the template point cloud plane; and vⱼᵢ represents the normal vector of the i^{th} sinking point in the target local point cloud j.

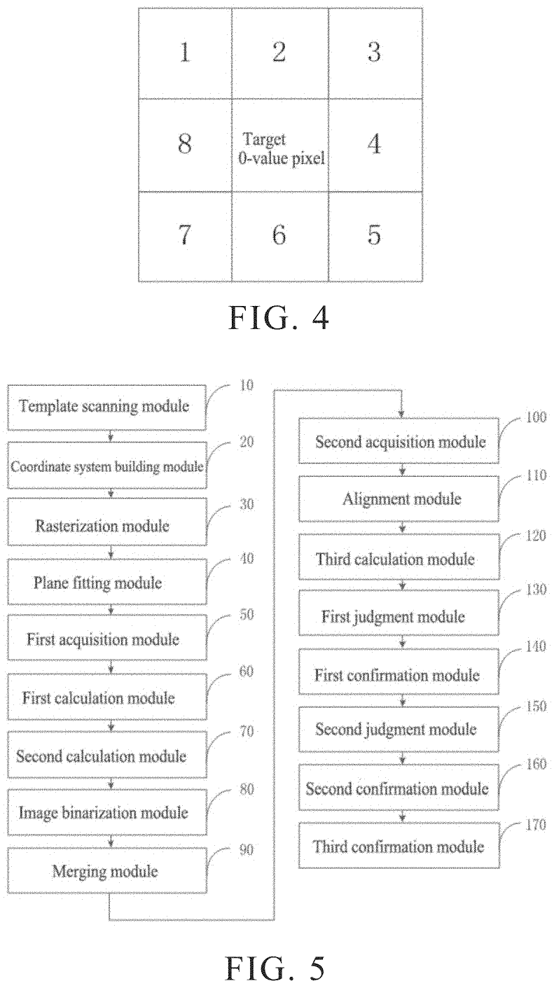

(S702) A target angle threshold β₀ is usually set as 5°. A sinking point in the target local point cloud corresponding to an angle rⱼᵢ less than the target angle threshold β₀ is determined as the cutting point. As shown in FIG. 4, a light-colored area is the sinking point, and a dark area is the cutting point. The area where the sinking point is located is wider than the area where the cutting point is located, so that the template cutting can be accurately extracted.

(S8) A point cloud image of the aircraft template is binarized to obtain outer contour points of the aircraft template. The outer contour points constitute an outer contour of the aircraft template.

(S801) Each point in the template point cloud is traversed. A distance between a target point in the template point cloud and a point closest to the target point is calculated.

(S802) A spatial resolution of the template point cloud is calculated according to the following formula:

$$l = \frac{1}{n} {\sum }_{i = 1}^{n} {d}_{i} ;$$

where l represents the spatial resolution of the template point cloud; n represents the total number of points in the template point cloud; and dᵢ represents a distance between an i^{th} point in the template point cloud and a point closest to the i^{th} point.

(S803) The X₁O₁Y₁ plane is divided into a plurality of grids with the spatial resolution as an interval to obtain a binary image. Each of the plurality of grids is a pixel of the binary image. An initial value of each pixel in the binary image is set to 0.

(S804) All points in the template point cloud are traversed. Pixels corresponding to grids where the points in the template point cloud are respectively located are set as 1-value pixels.

(S805) All 0-value pixels in the binary image are traversed. As shown in FIG. 4, a target 0-value pixel is set as a 1-value pixel, in surrounding 8 pixels of the target 0-value pixel, the number of 1-value pixels exceeds a target number. The target number is not more than 8, and 5 are optional.

(S806) All 1-value pixels in the binary image are traversed. A 1-value pixel adjacent to a 0-value pixel is taken as a contour pixel.

(S807) A point in a grid corresponding to the contour pixel is taken as the outer contour point of the aircraft template.

(S9) All cutting points and outer contour points of the aircraft template are merged to obtain a resulting point cloud.

(S10) A three-dimensional (3D) digital model of the aircraft template is obtained.

(S11) The 3D digital model is aligned with the resulting point cloud.

(S12) A distance between a target point in the 3D digital model and a corresponding point in the resulting point cloud is calculated to obtain an actual distance.

(S13) Whether the actual distance exceeds a preset distance threshold is determined.

If not, the aircraft template is qualified.

Otherwise, whether the number of points in the resulting point cloud of which the actual distance exceeds the preset distance threshold exceeds a preset number threshold is determined.

If not, the aircraft template is qualified.

Otherwise, the aircraft template is not qualified.

In steps (S9)-(S13), polyworks measurement software is used to import and align the 3D digital model and the resulting point cloud of the aircraft template. The distance between the target point in the 3D digital model and the corresponding point in the resulting point cloud is calculated to obtain the actual distance dᵣᵢ, and the points with the actual distance dᵣᵢ greater than 1 mm are removed at the same time. Each point in the 3D digital model is traversed, and an allowable tolerance, that is, the preset distance threshold, for the target point in the 3D digital model is set according to a lofting template aviation standard HB-240-89.

As shown in FIG. 5, a device for detecting defects in an aircraft template includes a template scanning module 10, a coordinate system building module 20, a rasterization module 30, a plane fitting module 40, a first acquisition module 50, a first calculation module 60, a second calculation module 70, an image binarization module 80, a merging module 90, a second acquisition module 100, an alignment module 110, a third calculation module 120, a first judgment module 130, a first confirmation module 140, a second judgment module 150, a second confirmation module 160 and a third confirmation module 170.

The template scanning module 10 is configured to scan a template to obtain a zero-mean template point cloud.

The coordinate system building module 20 is configured to establish a local coordinate system of a template point cloud based on the zero-mean template point cloud.

The rasterization module 30 is configured to rasterize the template point cloud to obtain a plurality of local point clouds.

The plane fitting module 40 is configured to fit a plane parameter of a target local point cloud to obtain a normal vector of the target local point cloud on a template point cloud plane and any point on the template point cloud plane.

The first acquisition module 50 is configured to acquire an average of normal vectors of all points in the target local point cloud.

The first calculation module 60 is configured to calculate a height of all points in the target local point cloud based on the average of the normal vectors of all points in the target local point cloud to obtain a sinking point in the target local point cloud.

The second calculation module 70 is configured to calculate an angle between a normal vector of the sinking point in the target local point cloud and a normal vector of the template point cloud plane where the sinking point is located to obtain a cutting point of the aircraft template; where all cutting points of the aircraft template constitute a cutting line.

The image binarization module 80 is configured to binarize a point cloud image of the aircraft template to obtain outer contour points of the aircraft template; where the outer contour points constitute an outer contour of the aircraft template.

The merging module 90 is configured to merge all cutting points and outer contour points of all the aircraft template to obtain a resulting point cloud.

The second acquisition module 100 is configured to acquire a three-dimensional (3D) digital model of the aircraft template.

The alignment module 110 is configured for aligning the 3D digital model with the resulting point cloud.

The third calculation module 120 is configured to calculate a distance between a target point in the 3D digital model and a corresponding point in the resulting point cloud to obtain an actual distance.

The first judgment module 130 is configured for judging whether the actual distance exceeds a preset distance threshold.

The first confirmation module 140 is configured to confirm that the aircraft template is qualified when the actual distance does not exceed the preset distance threshold.

The second judgment module 150 is configured for judging whether the number of points in the resulting point cloud of which the actual distance exceeds the preset distance threshold exceeds a preset number threshold when the first judgment module determines that the actual distance exceeds the preset distance threshold.

The second confirmation module 160 is configured to confirm that the aircraft template is qualified when the number of points in the resulting point cloud of which the actual distance exceeds the preset distance threshold does not exceed the preset number threshold.

The third confirmation module 170 is configured to confirm that the aircraft template is unqualified when the number of points in the resulting point cloud of which the actual distance exceeds the preset distance threshold exceeds the preset number threshold.

In an embodiment, the coordinate system building module 20 includes a first calculating unit, a second calculating unit and a building unit.

The first calculating unit is configured to calculate a product of a 3×n matrix formed from the zero-mean template point cloud and a transpose matrix of the 3×n matrix to obtain a covariance matrix; where n represents the number of points in the zero-mean template point cloud.

The second calculating unit is configured to calculate three eigenvectors a₁, a₂ and a₃ of the covariance matrix which are mutually orthogonal; where λ₁ is an eigenvalue of a₁, λ₂ is an eigenvalue of a₂, λ₃ is an eigenvalue of a₃, and λ₁>λ₂>λ₃.

The building unit is configured to establish the local coordinate system of the template point cloud by taking the three eigenvectors a₁, a₂ and a₃ respectively as X₁-axis direction, Y₁-axis direction and Z₁-axis directions of the local coordinate system, and taking a zero point O₁ as an origin of the local coordinate system.

In an embodiment, the first calculation module 60 includes a third calculating unit and a height threshold setting unit.

The third calculating unit is configured to calculate the heights of all the points in the target local point cloud according to the following formula:

$${h}_{ji} = \{ \begin{matrix}\frac{( {p}_{ji} - {p}_{j 0} ) \cdot {v}_{j}}{\vert {v}_{j} \vert} & , {v}_{j} \cdot {\overline{v}}_{j} < 0 \\ \frac{( {p}_{j 0} - {p}_{ji} ) \cdot {v}_{j}}{\vert {v}_{j} \vert} & , {v}_{j} \cdot {\overline{v}}_{j} \geq 0\end{matrix} ;$$

where v̅ⱼ̅ represents an average of normal vectors of all points in a target local point cloud j; vⱼ represents a normal vector of the target local point cloud j on the template point cloud plane; pⱼᵢ represents an i^{th} point in the target local point cloud j; pⱼ₀ represents any point in the target local point cloud j; and hⱼᵢ represents a height of the i^{th} point in the target local point cloud j.

The height threshold setting unit is configured to set a target height threshold. A point in the target local point cloud whose height is less than the target height threshold is the sinking point.

In an embodiment, the second calculation module 70 includes a fourth calculating unit and an angle threshold setting unit.

The fourth calculating unit is configured to calculate the angle between the normal vector of the sinking point in the target local point cloud and the normal vector of the template point cloud plane where the sinking point is located according to the following formula:

$${r}_{ji} = arccos \frac{{v}_{ji} \cdot {v}_{j}}{\vert {v}_{j} \vert} ;$$

where rⱼᵢ represents an angle between a normal vector of an i^{th} sinking point in a target local point cloud j and a normal vector of a template point cloud plane where the i^{th} sinking point is located; vⱼ represents a normal vector of the target local point cloud j on the template point cloud plane; and vⱼᵢ represents the normal vector of the i^{th} sinking point in the target local point cloud j.

The angle threshold setting unit is configured to set a target angle threshold; a sinking point in the target local point cloud corresponding to an angle less than the target angle threshold is the cutting point.

In an embodiment, the image binarization module 80 includes a fifth calculating unit, a sixth calculating unit, a rasterizing unit, a first pixel setting unit, a second pixel setting unit, a contour pixel extraction unit and an outer contour point extraction point.

The fifth calculating unit is configured to calculate a distance between a target point in the template point cloud and a point closest to the target point.

The sixth calculating unit is configured to calculate a spatial resolution of the template point cloud according to the following formula:

$$l = \frac{1}{n} {\sum }_{i = 1}^{n} {d}_{i} ;$$

where l represents the spatial resolution of the template point cloud; n represents the total number of points in the template point cloud; and dᵢ represents a distance between an i^{th} point in the template point cloud and a point closest to the i^{th} point.

The rasterizing unit is configured to divide the X₁O₁Y₁ plane into a plurality of grids with the spatial resolution as an interval to obtain a binary image. Each of the plurality of grids is a pixel of the binary image. An initial value of each pixel in the binary image is set to 0.

The first pixel setting unit is configured to traverse all points in the template point cloud and set pixels corresponding to grids where the points in the template point cloud are respectively located as 1-value pixels.

The second pixel setting unit is configured to traverse all 0-value pixels in the binary image and set a target 0-value pixel as a 1-value pixel, in surrounding 8 pixels of the target 0-value pixel, the number of 1-value pixels exceeds a target number.

The contour pixel extraction unit is configured to traverse all 1-value pixels in the binary image and taking a 1-value pixel adjacent to a 0-value pixel as a contour pixel.

The outer contour point extraction point is configured to take a point in a grid corresponding to the contour pixel as the outer contour point of the aircraft template.

The same and similar parts among various embodiments in this specification can be referred to each other. Especially for the device embodiments, since they are basically similar to the method embodiments, the related description is simplified, and it is feasible to refer to the corresponding description in the method embodiments.

Described above are only preferred embodiments of the present disclosure and are not intended to limit the present disclosure. It should be understood that any modifications, replacements and improvements made by those skilled in the art without departing from the spirit and scope of the present disclosure should fall within the scope of the present disclosure defined by the appended claims.

What is claimed is:

1. A method for detecting defects in an aircraft template, comprising:
(S1) scanning the aircraft template to obtain a zero-mean template point cloud;
(S2) establishing a local coordinate system of a template point cloud based on the zero-mean template point cloud;
(S3) rasterizing the template point cloud to obtain a plurality of local point clouds;
(S4) fitting a plane parameter of a target local point cloud to obtain a normal vector of the target local point cloud on a template point cloud plane and any point on the template point cloud plane;
(S5) acquiring an average of normal vectors of all points in the target local point cloud;
(S6) calculating a height of all points in the target local point cloud based on the average of the normal vectors of all points in the target local point cloud to obtain a sinking point in the target local point cloud;
(S7) calculating an angle between a normal vector of the sinking point in the target local point cloud and a normal vector of the template point cloud plane where the sinking point is located to obtain a cutting point of the aircraft template; wherein all cutting points of the aircraft template constitute a cutting line;
(S8) binarizing a point cloud image of the aircraft template to obtain outer contour points of the aircraft template; wherein the outer contour points constitute an outer contour of the aircraft template;
(S9) merging all cutting points and outer contour points of the aircraft template to obtain a resulting point cloud;
(S10) obtaining a three-dimensional (3D) digital model of the aircraft template;
(S11) aligning the 3D digital model with the resulting point cloud;
(S12) calculating a distance between a target point in the 3D digital model and a corresponding point in the resulting point cloud to obtain an actual distance; and
(S13) determining whether the actual distance exceeds a preset distance threshold;
if not, confirming that the aircraft template is qualified;
otherwise, determining whether the number of points in the resulting point cloud of which the actual distance exceeds the preset distance threshold exceeds a preset number threshold;
if not, confirming that the aircraft template is qualified;
otherwise, determining that the aircraft template is not qualified.

2. The method of claim 1, wherein the step (S2) is performed through steps of:
(S201) calculating a product of a 3×n matrix formed from the zero-mean template point cloud and a transpose matrix of the 3×n matrix to obtain a covariance matrix; wherein n represents the number of points in the zero-mean template point cloud;
(S202) calculating three eigenvectors a₁, a₂ and a₃ of the covariance matrix which are mutually orthogonal; wherein λ₁ is an eigenvalue of a₁, λ₂ is an eigenvalue of a₂, λ₃ is an eigenvalue of a₃, and λ₁>λ₂>λ₃; and
(S203) establishing the local coordinate system of the template point cloud by taking the three eigenvectors a₁, a₂ and a₃ respectively as X₁-axis direction, Y₁-axis direction and Z₁-axis direction of the local coordinate system, and taking a zero point O₁ as an origin of the local coordinate system.

3. The method of claim 1, wherein the step (S6) is performed through steps of:
(S601) calculating the height of all points in the target local point cloud according to the following formula:
$${h}_{ji} = \{ \begin{matrix}\frac{( {p}_{ji} - {p}_{j 0} ) \cdot {v}_{j}}{\vert {v}_{j} \vert} & , {v}_{j} \cdot {\overline{v}}_{j} < 0 \\ \frac{( {p}_{j 0} - {p}_{ji} ) \cdot {v}_{j}}{\vert {v}_{j} \vert} & , {v}_{j} \cdot {\overline{v}}_{j} \geq 0\end{matrix} ;$$
wherein v̅ⱼ̅ represents an average of normal vectors of all points in a target local point cloud j; vⱼ represents a normal vector of the target local point cloud j on the template point cloud plane; pⱼᵢ represents an i^{th} point in the target local point cloud j; pⱼ₀ represents any point in the target local point cloud j; and hⱼᵢ represents a height of the i^{th} point in the target local point cloud j; and
(S602) setting a target height threshold; wherein a point in the target local point cloud whose height is less than the target height threshold is the sinking point.

4. The method of claim 1, wherein the step (S7) is performed through steps of:
(S701) calculating the angle between the normal vector of the sinking point in the target local point cloud and the normal vector of the template point cloud plane where the sinking point is located according to the following formula:
$${r}_{ji} = arccos \frac{{v}_{ji} \cdot {v}_{j}}{\vert {v}_{j} \vert} ;$$
wherein rⱼᵢ represents an angle between a normal vector of an i^{th} sinking point in a target local point cloud j and a normal vector of a template point cloud plane where the i^{th} sinking point is located; vⱼ represents a normal vector of the target local point cloud j on the template point cloud plane; and vⱼᵢ represents the normal vector of the i^{th} sinking point in the target local point cloud j; and
(S702) setting a target angle threshold; wherein a sinking point in the target local point cloud corresponding to an angle less than the target angle threshold is the cutting point.

5. The method of claim 1, wherein the step (S8) is performed through steps of:
(S801) calculating a distance between a target point in the template point cloud and a point closest to the target point;
(S802) calculating a spatial resolution of the template point cloud according to the following formula:
$$l = \frac{1}{n} {\sum }_{i = 1}^{n} {d}_{i} ;$$
wherein l represents the spatial resolution of the template point cloud; n represents the total number of points in the template point cloud; and dᵢ represents a distance between an i^{th} point in the template point cloud and a point closest to the i^{th} point;
(S803) dividing an X₁O₁Y₁ plane into a plurality of grids with the spatial resolution as an interval to obtain a binary image; wherein each of the plurality of grids is a pixel of the binary image; and an initial value of each pixel in the binary image is set to 0;
(S804) traversing all points in the template point cloud, and setting pixels corresponding to grids where the points in the template point cloud are respectively located as 1-value pixels;
(S805) traversing all 0-value pixels in the binary image, and setting a target 0-value pixel as a 1-value pixel, wherein in surrounding 8 pixels of the target 0-value pixel, the number of 1-value pixels exceeds a target number;
(S806) traversing all 1-value pixels in the binary image, and taking a 1-value pixel adjacent to a 0-value pixel as a contour pixel; and
(S807) taking a point in a grid corresponding to the contour pixel as the outer contour point of the aircraft template.

6. A device for detecting defects in an aircraft template, comprising:
a template scanning module;
a coordinate system building module;
a rasterization module;
a plane fitting module;
a first acquisition module;
a first calculation module;
a second calculation module;
an image binarization module;
a merging module;
a second acquisition module;
an alignment module;
a third calculation module;
a first judgment module;
a first confirmation module;
a second judgment module;
a second confirmation module; and
a third confirmation module;
wherein the template scanning module is configured to scan the aircraft template to obtain a zero-mean template point cloud;
the coordinate system building module is configured to establish a local coordinate system of a template point cloud based on the zero-mean template point cloud;
the rasterization module is configured to rasterize the template point cloud to obtain a plurality of local point clouds;
the plane fitting module is configured to fit a plane parameter of a target local point cloud to obtain a normal vector of the target local point cloud on a template point cloud plane and any point on the template point cloud plane;
the first acquisition module is configured to acquire an average of normal vectors of all points in the target local point cloud;
the first calculation module is configured to calculate a height of all points in the target local point cloud based on the average of the normal vectors of all points in the target local point cloud to obtain a sinking point in the target local point cloud;
the second calculation module is configured to calculate an angle between a normal vector of the sinking point in the target local point cloud and a normal vector of the template point cloud plane where the sinking point is located to obtain a cutting point of the aircraft template; wherein all cutting points of the aircraft template constitute a cutting line;
the image binarization module is configured to binarize a point cloud image of the aircraft template to obtain outer contour points of the aircraft template; wherein the outer contour points constitute an outer contour of the aircraft template;
the merging module is configured to merge all cutting points and outer contour points of the aircraft template to obtain a resulting point cloud;
the second acquisition module is configured to acquire a three-dimensional (3D) digital model of the aircraft template;
the alignment module is configured for aligning the 3D digital model with the resulting point cloud;
the third calculation module is configured to calculate a distance between a target point in the 3D digital model and a corresponding point in the resulting point cloud to obtain an actual distance;
the first judgment module is configured for judging whether the actual distance exceeds a preset distance threshold;
the first confirmation module is configured to confirm that the aircraft template is qualified when the actual distance does not exceed the preset distance threshold;
the second judgment module is configured for judging whether the number of points in the resulting point cloud of which the actual distance exceeds the preset distance threshold exceeds a preset number threshold when the first judgment module determines that the actual distance exceeds the preset distance threshold;
the second confirmation module is configured to confirm that the aircraft template is qualified when the number of points in the resulting point cloud of which the actual distance exceeds the preset distance threshold does not exceed the preset number threshold; and
the third confirmation module is configured to confirm that the aircraft template is unqualified when the number of points in the resulting point cloud of which the actual distance exceeds the preset distance threshold exceeds the preset number threshold.

7. The device of claim 6, wherein the coordinate system building module comprises:
a first calculating unit;
a second calculating unit; and
a building unit;
wherein the first calculating unit is configured to calculate a product of a 3×n matrix formed from the zero-mean template point cloud and a transpose matrix of the 3×n matrix to obtain a covariance matrix; wherein n represents the number of points in the zero-mean template point cloud;
the second calculating unit is configured to calculate three eigenvectors a₁, a₂ and a₃ of the covariance matrix which are mutually orthogonal; wherein λ₁ is an eigenvalue of a₁, λ₂ is an eigenvalue of a₂, λ₃ is an eigenvalue of a₃, and λ₁>λ₂>λ₃; and
the building unit is configured to establish the local coordinate system of the template point cloud by taking the three eigenvectors a₁, a₂ and a₃ respectively as X₁-axis direction, Y₁-axis direction and Z₁-axis direction of the local coordinate system, and taking a zero point O₁ as an origin of the local coordinate system.

8. The device of claim 6, wherein the first calculation module comprises:
a calculating unit; and
a height threshold setting unit;
wherein the calculating unit is configured to calculate the height of all the points in the target local point cloud according to the following formula:
$${h}_{ji} = \{ \begin{matrix}\frac{( {p}_{ji} - {p}_{j 0} ) \cdot {v}_{j}}{\vert {v}_{j} \vert} & , {v}_{j} \cdot {\overline{v}}_{j} < 0 \\ \frac{( {p}_{j 0} - {p}_{ji} ) \cdot {v}_{j}}{\vert {v}_{j} \vert} & , {v}_{j} \cdot {\overline{v}}_{j} \geq 0\end{matrix} ;$$
wherein v̅ⱼ̅ represents an average of normal vectors of all points in a target local point cloud j; vⱼ represents a normal vector of the target local point cloud j on the template point cloud plane; pⱼᵢ represents an i^{th} point in the target local point cloud j; pⱼ₀ represents any point in the target local point cloud j; and hⱼᵢ represents a height of the i^{th} point in the target local point cloud j; and
the height threshold setting unit is configured to set a target height threshold; wherein a point in the target local point cloud whose height is less than the target height threshold is the sinking point.

9. The device of claim 6, wherein the second calculation module comprises:
a calculating unit; and
an angle threshold setting unit;
wherein the calculating unit is configured to calculate the angle between the normal vector of the sinking point in the target local point cloud and the normal vector of the template point cloud plane where the sinking point is located according to the following formula:
$${r}_{ji} = arccos \frac{{v}_{ji} \cdot {v}_{j}}{\vert {v}_{j} \vert} ;$$
wherein rⱼᵢ represents an angle between a normal vector of an i^{th} sinking point in a target local point cloud j and a normal vector of a template point cloud plane where the i^{th} sinking point is located; vⱼ represents a normal vector of the target local point cloud j on the template point cloud plane; and vⱼᵢ represents the normal vector of the i^{th} sinking point in the target local point cloud j; and
the angle threshold setting unit is configured to set a target angle threshold; wherein a sinking point in the target local point cloud corresponding to an angle less than the target angle threshold is the cutting point.

10. The device of claim 6, wherein the image binarization module comprises:
a first calculating unit;
a second calculating unit;
a rasterizing unit;
a first pixel setting unit;
a second pixel setting unit;
a contour pixel extraction unit; and
an outer contour point extraction point;
wherein the first calculating unit is configured to calculate a distance between a target point in the template point cloud and a point closest to the target point;
the second calculating unit is configured to calculate a spatial resolution of the template point cloud according to the following formula:
$$l = \frac{1}{n} {\sum }_{i = 1}^{n} {d}_{i} ;$$
wherein l represents the spatial resolution of the template point cloud; n represents the total number of points in the template point cloud; dᵢ represents a distance between an i^{th} point in the template point cloud and a point closest to the i^{th} point;
the rasterizing unit is configured to divide an X₁O₁Y₁ plane into a plurality of grids with the spatial resolution as an interval to obtain a binary image; wherein each of the plurality of grids is a pixel of the binary image; and an initial value of each pixel in the binary image is set to 0;
the first pixel setting unit is configured to traverse all points in the template point cloud and set pixels corresponding to grids where the points in the template point cloud are respectively located as 1-value pixels;
the second pixel setting unit is configured to traverse all 0-value pixels in the binary image and set a target 0-value pixel as a 1-value pixel, wherein in surrounding 8 pixels of the target 0-value pixel, the number of 1-value pixels exceeds a target number;
the contour pixel extraction unit is configured to traverse all 1-value pixels in the binary image and taking a 1-value pixel adjacent to a 0-value pixel as a contour pixel; and
the outer contour point extraction point is configured to take a point in a grid corresponding to the contour pixel as the outer contour point of the aircraft template.
